(19) United States
(12) Patent Application Publication
(10) Pub. No.: US 2012/0258582 A1
(43) Pub. Date: Oct. 11, 2012

(54) METHOD AND APPARATUS FOR SELECTIVELY GROWING DOPED EPITAXIAL FILM

(75) Inventors: Takuya SEINO, Kawasaki-shi (JP); Junko ONO, Tokyo (JP); Kimiko MASHIMO, Tokyo (JP); Hiroki DATE, Tokyo (JP)

(73) Assignee: CANON ANELVA CORPORATION, Kawasaki-shi (JP)

(21) Appl. No.: 13/478,854

(22) Filed: May 23, 2012

Related U.S. Application Data
(63) Continuation of application No. PCT/JP2010/073169, filed on Dec. 22, 2010.

(30) Foreign Application Priority Data
Dec. 22, 2009 (JP) 2009-289961

(51) Int. Cl. H01L 21/20

(52) U.S. Cl. 438/478; 257/E21.09

(57) ABSTRACT

In one embodiment of the present invention, the processing surface of a substrate having at least a single crystal surface and a dielectric surface is exposed to a first deposition gas containing a source gas and a doping gas to form a first doped thin film on the single crystal surface, whereas supply of the first deposition gas is stopped before a film is formed on the dielectric surface. Next, the processing surface of the substrate is exposed to a second deposition gas containing a source gas and a doping gas to form a second thin film doped with less dopant than the first thin film on the single crystal surface, whereas supply of the second deposition gas is stopped before a film is formed on the dielectric surface. Subsequently, the processing surface of the substrate is exposed to a chlorine-containing gas to be etched.

### CROSS-REFERENCES TO RELATED APPLICATIONS

This application is a continuation application of International Application No. PCT/JP2010/073169, filed Dec. 22, 2010, which claims the benefit of Japanese Patent Application No. 2009-289961, filed Dec. 22, 2009. The contents of the aforementioned applications are incorporated herein by reference in their entireties.

### TECHNICAL FIELD

The present invention relates to a method and an apparatus for selectively growing an In-Situ-doped epitaxial film with doping during the growth of the epitaxial film.

### BACKGROUND ART

The density growth and the further integration of semiconductor devices have reduced the gate length. Particularly, in a CMOS (Complementary Metal Oxide Semiconductor), reduction in the gate length causes deterioration in electrical characteristics called a “short channel effect”, which leads to a problem such as an increase in leak current. As technologies to solve such a problem, there have been proposed a method of improving the mobility by distorting the lattice of an epitaxial layer in a channel portion with application of stress to the epitaxial layer, and a method of forming a very thin source/drain layer.

In the method of distorting the epitaxial layer in the channel portion, it is effective to add a material having a lattice constant different from that of Si to the source/drain layer. For example, in an n-type MOSFET (Metal Oxide Semiconductor Field Effect Transistor), the mobility is improved by applying tensile strain to a channel layer using SiC blended C, for example, having a lattice constant smaller than Si. Meanwhile, in a p-type MOSFET, the mobility is improved by applying compressive strain to a channel layer using SiGe blended Ge, for example, having a lattice constant larger than Si. Moreover, the source/drain layer and an electrode need to be electrically connected to each other with low resistance. Thus, it is imperative to perform doping using B (boron), P (phosphorus), As (arsenic) or the like. While ion implantation is usually used for doping of the source/drain layer, activation annealing at high temperature is required to generate carriers after the doping.

With reference to FIGS. 13A to 13G, a conventional method for forming a source/drain layer is described. In FIG. 13A, a gate electrode 53 is disposed on a Si substrate 51 with a gate insulating film 52 interposed therebetween, and sidewalls 54 formed of silicon oxide films are formed on both sides of the gate electrode 53. Although not shown in the drawings, a large number of these gate electrodes 53, gate insulating films 52 and sidewalls 54 are provided on the Si substrate 51 with element isolation regions 55 provided therebetween.

By use of the conventional method, a Si substrate is prepared in Step S131, in which a large number of patterns each having the structure as shown in FIG. 13A are formed.

Next, in Step S131, recess etching is performed on the structure shown in FIG. 13A to recess the silicon surface. More specifically, the silicon surface exposed on the Si substrate 51 is etched by using anisotropic etching and isotropic etching in combination, thereby obtaining the shape as shown in FIG. 13B.

Then, in Step S132, light etching such as chemical dry etching (CDE) is performed on the Si surface roughened by the recess etching step to remove a damaged layer D, thus obtaining the state shown in FIG. 13C.

In Step S133, a selectively grown layer 57 is formed by epitaxially growing a Si-containing film such as SiGe or SiC, using a conventional selective growth technology, only on the Si surface of the substrate having the damaged layer removed therefrom shown in FIG. 13C. Thus, the state shown in FIG. 13D is obtained. In this process, it is necessary to epitaxially grow the Si-containing film such as SiGe or SiC only on the exposed Si surface without forming the Si-containing film on the element isolation regions 55, sidewalls 54 and gate insulating film 52, which are formed of dielectric films such as silicon oxide films.

The selective growth technology used in this case is a technology of selectively growing a Si epitaxial film by alternately performing Si growth and Cl₂ gas etching using Si₂H₆ (disilane) and Cl₂ (chlorine) gas, for example (see Patent Document 1). In order to grow SiC, C-containing gas is added during deposition, so that SiC can be epitaxially selectively grown only on the Si surface. In order to grow SiGe, Ge-containing gas such as GeH₄ is added together with Si₂H₆ (disilane), so that a SiGe film can be epitaxially selectively grown only on the Si surface.

Thereafter, in Step S134, P, As or the like is ion-implanted for an n-type MOSFET, while B is ion-implanted for a p-type MOSFET (FIG. 13E). However, since the dopant is not activated by being just ion-implanted, activation annealing is performed in Step S135 to complete a source/drain layer 59 (FIG. 13F).

The conventional source/drain layer formation method using the ion-implantation shown in FIGS. 13A to 13G has a problem that the low resistance causes insufficient activation even after high-concentration doping. Moreover, there are also problems that the activation annealing causes the surface roughness, and recrystallizes the source/drain layer, making it difficult to control the distortion amount. Furthermore, there is a problem that, when the activation annealing is performed, thermal diffusion of the implanted dopant does not allow formation of a very thin source/drain layer.

One of the conceivable solutions is to selectively grow the source/drain layer by applying doping gas simultaneously with deposition without performing the ion implantation, as shown in FIGS. 14A to 14E. This technology is called In-Situ doping. Next, description is given of a source/drain layer formation method using the In-Situ doping selective growth shown in FIGS. 14A to 14E. FIG. 14A is a schematic view of the same structure as that shown in FIG. 13A. Here, the process from Step S141 of recess etching shown in FIG. 14B to Step S142 of removing a damaged layer by light etching shown in FIG. 14C is the same as that of Steps S131 and S132 (FIGS. 13A to 13C). In the next selective growth process in Step S143, a source/drain layer 56 is formed through In-Situ doping selective growth by adding dopant gas to deposition gas for In-Situ doping (FIG. 14D).

Comparing the source/drain layer formation method by the In-Situ doping selective growth shown in FIGS. 14A to 14E with the formation method shown in FIGS. 13A to 13G, the In-Situ doping selective growth method can omit two steps, i.e., Step S134 shown in FIG. 13E and Step S135 shown in FIG. 13F. As a result, impurity adsorption can be suppressed, and the processing time can be reduced.

### CITATION LIST

### Patent Literature

PTL 1: Japanese Patent Application Laid-open No. Hei 7-15888

### SUMMARY OF INVENTION

However, it has been difficult to put into practical use the conventional source/drain layer formation method using the In-Situ doping selective growth, especially the one involving addition of high concentration of P. Even in the technology of selectively growing a Si epitaxial film, disclosed in Patent Literature 1, by alternately performing Si growth using Si₂H₆ and Cl₂ gases and etching using the Cl₂ gas, there is no mention made on the case of doping P at high concentration.

When P is doped simultaneously with the deposition in the technology described above, the surface flatness of the selectively grown Si-containing film is deteriorated if PH₃ (phosphine) is simply supplied as the doping gas. More specifically, when selective growth is performed, in which the Si-containing gas such as Si₂H₆ and PH₃ for In-Situ doping are simultaneously supplied and etching is performed using halogen gas such as Cl₂, surface roughness occurs in the epitaxial film doped with high concentration of P. When the surface roughness occurs, there arises a problem that the properties of the gate insulating film in the channel portion are deteriorated, i.e., device characteristics are deteriorated due to an increase in contact resistance of the source/drain layer with electrodes.

It is an object of the present invention to provide a method and an apparatus for selectively growing an In-Situ-doped epitaxial film, capable of improving the surface roughness of an epitaxial film having a high concentration doping, and decreasing contact resistance of a source/drain layer with electrodes to improve device characteristics.

A configuration according to an aspect of the present invention to achieve the foregoing object is as follows.

Specifically, a method for selectively growing an In-Situ doped epitaxial film according to the present invention comprises: a first step of forming, by epitaxial growth, a first thin film doped with a dopant on a single crystal surface of a substrate having the single crystal surface and a dielectric surface as a processing surface; a second step of forming, by epitaxial growth, a second thin film doped with the dopant at lower concentration than the first thin film, on a surface of the first thin film; and an etching step of removing a material adhering to the dielectric surface by exposing the processing surface of the substrate to an etching gas.

In addition, an apparatus for selectively growing an In-Situ doped epitaxial film according to the present invention comprises: a vacuum evacuatable chamber; a substrate holder provided in the chamber and capable of holding a substrate having at least a single crystal surface and a dielectric surface; a gas valve flow rate control system having a plurality of gas valves capable of atomic layer control for thin film, the gas valve flow rate control system configured to introduce a source gas, a doping gas containing a dopant and an etching gas into the chamber while controlling flow rates of the gases; and a control device configured to control the gas valve flow rate control system, wherein the control device controls the gas valve introduction system to cause the gas valve introduction system to sequentially execute a first introduction of introducing a first deposition gas containing the source gas and the doping gas into the chamber to expose a processing surface of the substrate to the source gas and the doping gas and thus form a first thin film doped with the dopant on the single crystal surface, a second introduction of introducing a second deposition gas containing at least the source gas into the chamber to expose the processing surface of the substrate to at least the source gas and thus form a second thin film doped with the dopant at lower concentration than the first thin film, on a surface of the first thin film, and a third introduction of introducing the etching gas into the chamber to expose the processing surface of the substrate to the etching gas and thus etch the processing surface.

According to the present invention, in selective growth of an In-Situ doped epitaxial film, the second thin film grown with low concentration dopant is formed after the highly-doped first thin film is formed, and then etching is performed by applying a chlorine-containing gas. In the second thin film doped with less dopant, no surface roughness is caused by the etching using the chlorine-containing gas, or the surface roughness is reduced. Thus, the surface roughness of the epitaxial film having a high concentration doping can be improved, and device characteristics can be improved even when contact resistance of source/drain layer with electrodes is decreased.

### BRIEF DESCRIPTION OF DRAWINGS

FIG. 1 is a schematic plan view of a multi-chamber CVD apparatus according to an embodiment of the present invention.

FIG. 2 is a schematic cross-sectional view of a deposition chamber in the CVD apparatus shown in FIG. 1.

FIG. 3 is a schematic view of a gas valve flow rate control system according to an embodiment of the present invention.

FIG. 4 is a flowchart showing a method for selectively growing an In-Situ doped epitaxial film according to an embodiment of the present invention.

FIG. 5 is an explanatory graph showing a relationship between a growth rate and a pattern opening area in the case of the use of the selective growth method according to an embodiment of the present invention.

FIG. 6 is an explanatory graph showing a relationship between a gas flow rate and a carbon concentration of epitaxial films in the case of the use of the selective growth method according to an embodiment of the present invention.

FIG. 7 is an explanatory graph showing a relationship between a gas flow rate and a P concentration in the case of the use of the selective growth method according to an embodiment of the present invention.

FIG. 8 is an explanatory view showing the selective growth method according to an embodiment of the present invention.

FIG. 9 is an explanatory view showing a part of a time chart for introduced gases according to an embodiment of the present invention.

FIG. 10A is a view showing an SEM photograph of a cross-section of an In-Situ P-doped SiC heteroepitaxial film according to an embodiment of the present invention.

FIG. 10B is a view showing an SEM photograph of a surface of the In-Situ P-doped SiC heteroepitaxial film shown in FIG. 10A.

FIG. 11 is an explanatory view showing a selective growth method according to a comparative example of the present invention.

FIG. 12A is a view showing an SEM photograph of a cross-section of an In-Situ P-doped SiC heteroepitaxial film according to a comparative example of the present invention.

FIG. 12B is a view showing an SEM photograph of a surface of the In-Situ P-doped SiC heteroepitaxial film shown in FIG. 12A.

FIG. 13A is an explanatory view showing a conventional source/drain formation process.

FIG. 13B is an explanatory view showing the conventional source/drain formation process.

FIG. 13C is an explanatory view showing the conventional source/drain formation process.

FIG. 13D is an explanatory view showing the conventional source/drain formation process.

FIG. 13E is an explanatory view showing the conventional source/drain formation process.

FIG. 13F is an explanatory view showing the conventional source/drain formation process.

FIG. 13G is a flowchart showing procedures of the conventional source/drain formation process.

FIG. 14A is an explanatory view showing a conventional source/drain formation process by In-Situ doping.

FIG. 14B is an explanatory view showing the conventional source/drain formation process by In-Situ doping.

FIG. 14C is an explanatory view showing the conventional source/drain formation process by In-Situ doping.

FIG. 14D is an explanatory view showing the conventional source/drain formation process by In-Situ doping.

FIG. 14E is a flowchart showing procedures of the conventional source/drain formation process by In-Situ doping.

### DESCRIPTION OF EMBODIMENTS

With reference to the drawings, an embodiment of the present invention is described below. However, the present invention is not limited to the embodiment.

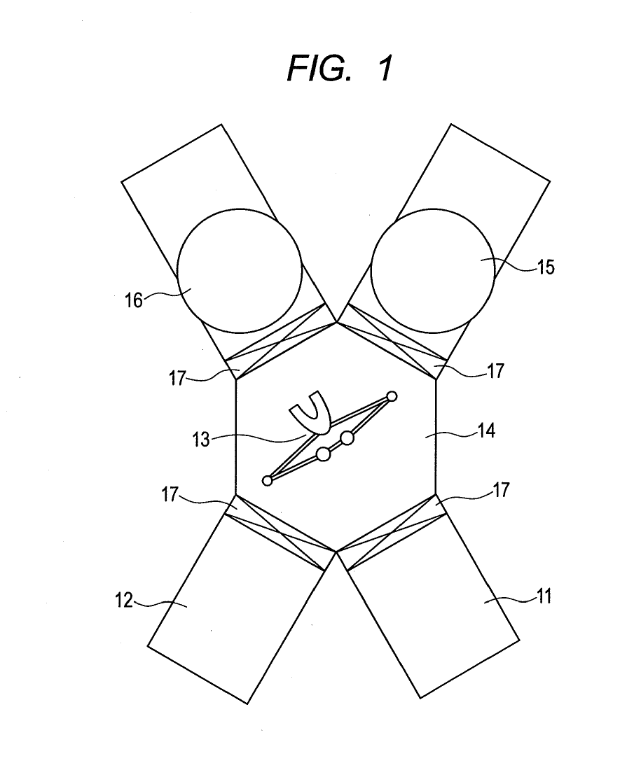

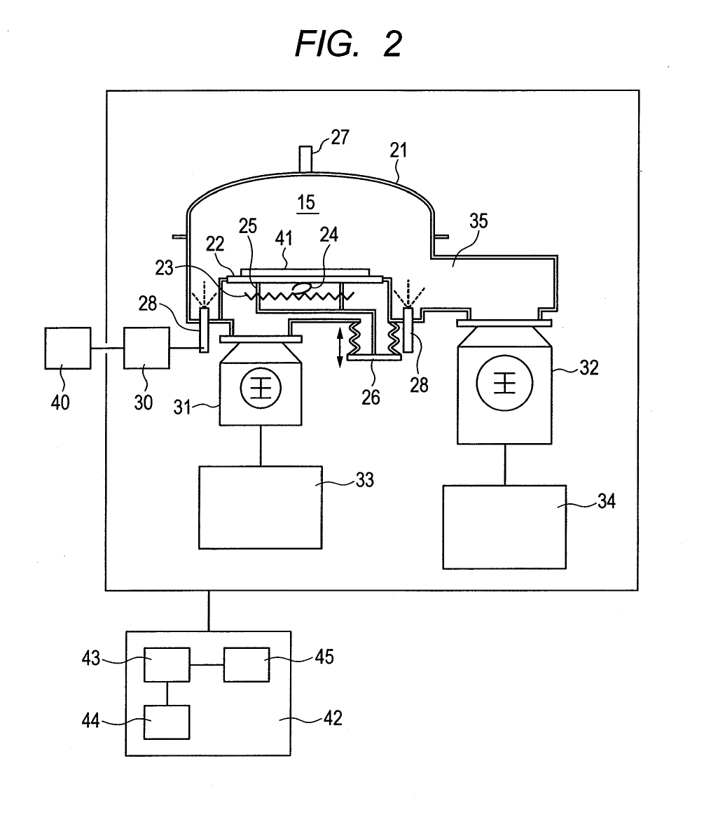

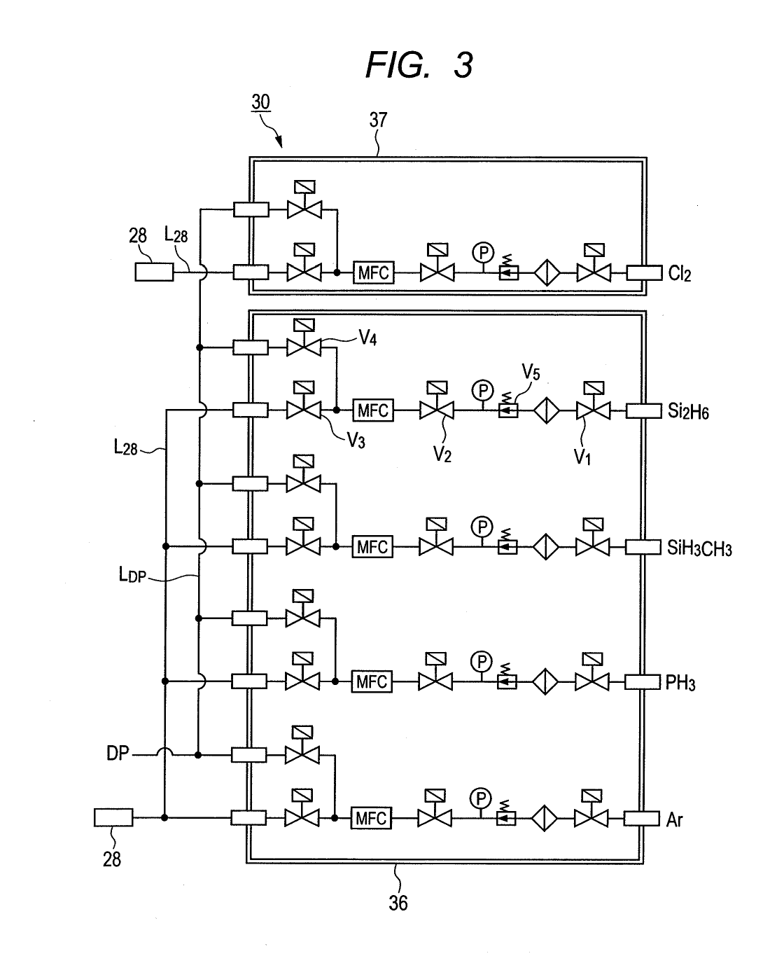

First, with reference to FIGS. 1 to 3, description is given of a method for selectively growing an In-Situ doped epitaxial film according to the present invention. FIG. 1 is a schematic plan view of a multi-chamber CVD apparatus. FIG. 2 is a schematic cross-sectional view of a deposition chamber in the CVD apparatus shown in FIG. 1. FIG. 3 is a schematic view of a gas valve flow rate control system.

As shown in FIGS. 1 and 2, an apparatus for selectively growing an epitaxial film according to this embodiment is, for example, a chemical vapor deposition (CVD) apparatus. The CVD apparatus includes: two exchange chambers 11, 12 for transferring a substrate 41 (see FIG. 2) between an atmospheric environment on the outside and a vacuum environment on the inside; a carrier chamber 14 including a carrier mechanism 13 for carrying the substrate 41 in the vacuum environment; and two deposition chambers 15, 16 for forming a silicon (Si) epitaxial film.

As the substrate 41, for example, an 8-inch Si (100) substrate having an oxide film patterned on its surface is used. The size of the substrate 41 is not particularly limited.

The exchange chambers 11, 12 can accommodate a multiple number of the 8-inch substrates 41 described above, for example. Moreover, gate valves 17 are provided between the exchange chambers 11, 12 and the carrier chamber 14 as well as between the carrier chamber 14 and the two deposition chambers 15, 16. The respective chambers 11, 12, and 14 to 16 are evacuated by independent evacuation means (here, a turbo-molecular pump).

As shown in FIG. 2, the deposition chamber 15 is partitioned by a chamber 21 which can be vacuum-evacuated. More specifically, the inside of the chamber 21 is evacuated by a turbo-molecular pump 32 for evacuating the process chamber through an evacuation port 35, and by a dry pump 34 for evacuating the process chamber, which is a pump located at a later stage of the turbo-molecular pump 32. On the outer wall of the chamber 21 of the deposition chamber 15, a chamber heater (not shown) for heating the deposition chamber 15 is provided. The chamber heater eliminates the moisture adsorbing to the chamber wall by heating the deposition chamber 15 after exposure to the atmosphere for maintenance or the like. The inside of the deposition chamber 15 is evacuated to ultrahigh vacuum of, for example, 5×10⁻⁷ Pa or less. Moreover, a pipe (not shown) capable of circulating a coolant is also provided on the outer wall of the chamber 21. During the deposition process, cooling water is circulated through the circulation pipe to maintain the temperature of the chamber 21 approximately at room temperature.

On a susceptor (substrate holder) 22 provided inside the chamber 21, the substrate 41 to be processed is disposed. The inside of the susceptor 22 is independently evacuated, and is not connected to the deposition space into which process gas is introduced. Moreover, the inside of the susceptor 22 is evacuated by a turbo-molecular pump 31 for evacuating the heater chamber, and by a dry pump 33 for evacuating the heater chamber, which is a pump located at a later stage of the turbo-molecular pump 31. Inside the susceptor 22, a heater 23 for heating the substrate is provided as a heating control system. A power feeding mechanism (not shown) feeds heating power to the heater 23. The temperature condition of the susceptor 22 is detected by a thermocouple 24. The susceptor 22 is controlled to have a required temperature by controlling the heating power of the heater 23.

A radiation thermometer (pyrometer) 27 is provided on the outside of the deposition chamber 15, and thereby the temperature of the substrate 41 mounted on the susceptor 22 is measured. The substrate 41 is disposed on the susceptor 22 with a device forming surface (processing surface) facing up. The susceptor 22 has three holes of 7 mm in diameter, for example. Through the holes, a lift pin 25 made of quartz, for example, is moved up and down by a lift pin lifting mechanism 26 connected thereto, thereby transferring the substrate 41 from the carrier mechanism 13 onto the susceptor 22. After the substrate 41 is mounted on the susceptor 22, the holes described above are sealed by the substrate 41 itself.

The deposition chamber 15 is also provided with a gas introduction part 28 for introducing a deposition gas including a source gas containing a material of a film to be selectively grown on the substrate 41, and a doping gas containing elements to be doped into the film to be selectively grown. As the deposition gas, a source gas containing semiconductor elements (one of SiH₄, Si₂H₆, GeH₄ and SiH₃CH₃, or a mixture thereof) to be the material of the film to be selectively grown on the substrate 41, and a doping gas (one of PH₃ and AsH₃, or a mixture thereof) containing a dopant such as P and As can be introduced in order to grow an In-Situ doped epitaxial film made of various materials on the substrate 41 with an oxide film pattern. Moreover, Cl₂ gas can be introduced as an etching gas. In this embodiment, the etching gas can be introduced into the deposition chamber 15 from the source gas introduction part 28.

The deposition gas and etching gas described above are called process gases. The process gases are supplied to a gas supply unit 30 separately through individual gas lines from a gas cylinder unit 40. Each of the process gases is supplied into a deposition space where the substrate 41 is placed inside the chamber 21 through the gas introduction part 28 after a gas flow rate thereof is controlled by the gas supply unit 30.

As shown in FIG. 3, the gas supply unit 30 is a gas valve flow rate control system capable of implementing atomic layer control for thin film, including multiple gas valves, and can instantly switch between the valves. The gas valve flow rate control system 30 includes a deposition gas supply system 36 and an etching gas supply system 37. In the example shown in FIG. 3, Si₂H₆ and SiH₃CH₃ supply systems as source gas introduction systems, a PH₃ supply system as a doping gas supply system and an Ar supply system as a diluent gas supply system are connected to the deposition gas supply system 36. The deposition gas supply system 36 is configured so that the supply of a predetermined amount of gas can be instantly switched between ON and OFF for each of the supply systems. Moreover, a Cl₂ supply system is connected to the etching gas supply system 37, and the etching gas supply system 37 is configured so that the supply of a predetermined amount of gas can be instantly switched between ON and OFF.

To be more specific, the supply systems described above have a supply line L₂₈ capable of supplying a gas having a predetermined flow rate from a gas supply source to the gas introduction part 28, and an evacuation line L_{DP} connected to a dry pump DP as evacuation means and capable of evacuating the gas inside the supply line L₂₈. A mass-flow controller MFC capable of controlling the gas flow rate is provided on the supply line L₂₈. Moreover, on the downstream side of the mass-flow controller MFC, a valve V₃ which can be opened and closed at a predetermined gas supply timing is provided to enable the supply of the gas for a predetermined period of time, the gas being controlled to have a predetermined flow rate. The evacuation line L_{Dp} is connected between the mass-flow controller MFC and the valve V3 to enable the supply of the gas strictly controlled to have the predetermined flow rate to the gas introduction part 28 for a predetermined period of time by evacuating the gas accumulated in the supply line L₂₈ until the valve V₃ is turned ON after the valve is once turned OFF.

More specifically, a valve V₂ on the upstream side of the mass-flow controller MFC is opened slightly before the predetermined gas supply timing to activate the mass-flow controller MFC. In this process, with the valve V₃ on the supply line L₂₈ closed and a valve V₄ on the evacuation line L_{Dp} opened, the gas outputted from the mass-flow controller MFC is evacuated to the evacuation line L_{Dp} until the supply amount becomes stable after the initial rise. Then, the gas adjusted to have the predetermined flow rate is supplied to the gas introduction part 28 at the predetermined gas supply timing by closing the valve V₄ on the evacuation line L_{Dp} and opening the valve V₃ on the supply line L₂₈. After the elapse of the predetermined period of time, the gas supply to the gas introduction part 28 is cut off by closing the valve V₃ on the supply line L₂₈, and the gas outputted from the mass-flow controller MFC is evacuated to the evacuation line L_{Dp}, by opening the valve V₄, until the predetermined gas supply timing comes as described above.

The valves V₂ to V₄ are diaphragm valves in this embodiment, and are opened and closed by high-pressure air through a solenoid-operated valve controlled for supply at high speed based on input of an instruction signal from a control device 42 (see FIG. 2) to be described later. In this embodiment, the valves V₂ to V₄ are operated at high speed in response to a control signal from the control device 42, and can perform an opening/closing operation within 0.1 second or less. Moreover, in FIG. 3, reference numeral V₁ is a valve manually operated when the device is used, while V₅ is a pressure reducing valve for preventing the pressure of the gas supply to the mass-flow controller MFC from getting too high.

Furthermore, the thermal CVD apparatus also includes a control device 42 capable of controlling the sequence for implementing the atomic layer control for thin film by instantly switching the operations of the entire apparatus, such as the substrate temperature, gas flow rate, pressure, standby time and evacuation. The control device 42 includes a storage unit 44 configured to store a control program, an arithmetic processing unit 43 configured to perform arithmetic processing for process control, and an input unit 45 configured to perform various setting input.

As the control device 42, a personal computer (PC), a microcomputer or the like can be used, for example. The storage unit 44 includes, for example, a ROM having control program, parameters and the like previously stored therein, a RAM having programs and data temporarily expanded as a work area, a hard disk (HDD) for storing control programs, processed data and the like. The arithmetic processing unit 43 is a CPU, which performs control of the respective units described above, various arithmetic processing and the like according to the programs. The input unit 45 performs input of value setting of various controls and the like, for example, or includes operation keys and the like for instructing the start and stop of the operation. As the input unit 45, general-purpose input media such as a keyboard, a touch panel and a mouse can be used, for example.

The control device 42 introduces a first deposition gas containing a Si-containing gas as a source gas and a doping gas into the chamber, and exposes the processing surface of the substrate 41 having a dielectric body formed thereon to the first deposition gas, thus forming a first thin film on the single crystal surface of the substrate (surface where selective growth is performed), and supply of the first deposition gas is stopped before a film is formed on the dielectric surface (a first deposition step). Next, the control device 42 introduces a second deposition gas containing a Si-containing gas as a source gas and a doping gas into the chamber, and exposes the processing surface of the substrate 41 to the second deposition gas, thus forming a second thin film on the single crystal surface of the substrate, and supply of the second deposition gas is stopped before a film is formed on the dielectric surface (a second deposition step). Subsequently, the control device 42 sequence-controls the apparatus for selectively growing the epitaxial film such that the processing surface of the substrate 41 exposed to a chlorine-containing gas as an etching gas to perform etching (an etching step). The control device 42 continuously sequence-controls the above series of operations more than once to grow an epitaxial film having a desired film thickness.

More specifically, the apparatus for selective growth according to this embodiment includes a heating control system 23 and the gas valve flow rate control system 30, and further includes the sequence control device 42 capable of controlling the operations of the entire apparatus. Thus, the apparatus can implement a selective growth technology capable of controlling In-Situ doped epitaxial films having various concentrations from low concentration to high concentration in the order of atomic layer.

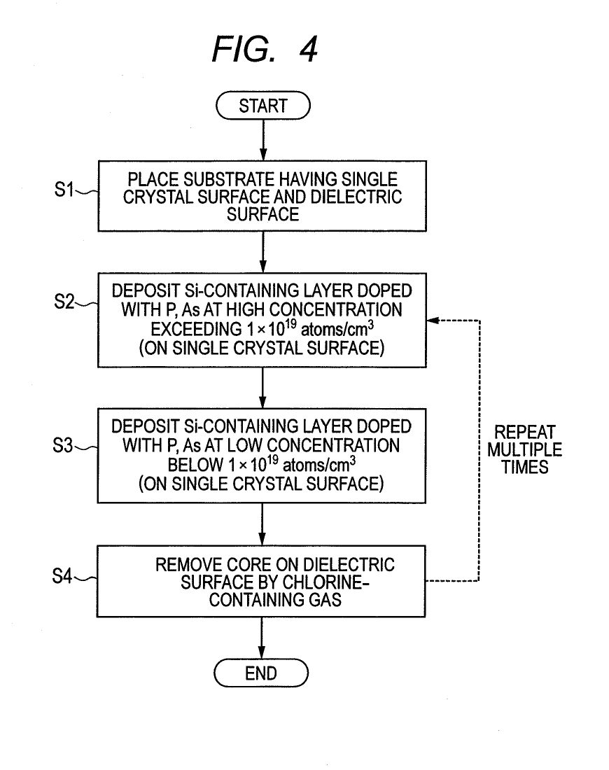

Next, description is given of a method for selectively growing an In-Situ doped epitaxial film according to the embodiment of the present invention carried out using the thermal CVD apparatus (the apparatus for selectively growing an epitaxial film) described above. FIG. 4 is a flowchart showing the method for selectively growing an In-Situ doped epitaxial film according to the embodiment of the present invention.

As shown in FIG. 4, the substrate 41 having the single crystal surface and the dielectric surface is carried into the chamber 21 of the thermal CVD apparatus and placed on the susceptor 22 (Step 1; hereinafter described as “S1”). Here, the single crystal is, for example, single crystal silicon (Si (100)) or the like, while the dielectric is, for example, a silicon oxide film, a silicon nitride film or the like. Then, the heater 23 is controlled so that the substrate temperature is previously increased to the temperature for the next deposition step.

Next, as shown in FIG. 4, a first deposition step is performed (S2). In this deposition step, a Si-containing film (first thin film) doped with high concentration of dopant (e.g., phosphorus (P)) is formed. Here, the highly doped film means one having a dopant concentration, e.g., P concentration exceeding 5×10¹⁹ atoms/cm³. In this deposition step, the Si-containing gas, e.g., SiH₄, Si₂H₆, Si₃H₈, SiH₃CH₃ or the like is appropriately supplied as the source gas. At the same time, a P-containing gas, e.g., PH₃ is supplied at a first flow ratio as the doping gas. In this process, by appropriately setting the temperature of the substrate 41 to be higher than the pyrolysis temperature of the Si-containing gas and to be lower than the allowable temperature of the device, a Si-containing film In-Situ doped with P is epitaxially grown on the single crystal surface.

In this process, film formation on the dielectric surface, i.e., the silicon oxide film surface or silicon nitride film surface starts later than that on the single crystal surface such as Si. When a film is epitaxially grown on the single crystal surface such as Si and no film is formed yet on the dielectric surface such as the silicon oxide film surface or silicon nitride film surface, the first deposition step is terminated. Note that germanium (Ge) may be added to the Si-containing film. In this case, a Ge-containing gas, e.g., a GeH₄ gas is added together with the Si-containing gas, as the source gas.

Next, in FIG. 4, a second deposition step is performed (S3). In this deposition step, a Si-containing film (second thin film) is formed, which is doped with lower concentration of P than the first thin film. Here, the low-concentration film means one having a concentration of 1×10¹⁹ atoms/cm³ or less. While the Si-containing gas is also supplied in the second deposition step, as in the case of the first deposition step, the doping concentration is appropriately adjusted to 1×10¹⁹ atoms/cm³ or less by simultaneously supplying a smaller volume of the doping gas at a second flow ratio. In this process, no doping gas may be supplied. The second deposition step is terminated after a film is epitaxially grown on the single crystal surface such as Si, i.e., the surface of the Si-containing film deposited and epitaxially grown in the first deposition step, and before a film is formed on the dielectric surface such as the silicon oxide film surface or silicon nitride film surface. Note that Ge may be added to the Si-containing film. In this case, a Ge-containing gas, e.g., a GeH₄ gas is added together with the Si-containing gas, as the source gas. The second flow ratio is smaller than the first flow ratio, and can be intentionally set to zero without performing the doping gas supply.

Next, in FIG. 4, an etching step is performed (S4). In the etching step, a core formed on the dielectric surface such as the silicon oxide film surface or silicon nitride film surface, or deposited or attached matter that is a precursor of the core, i.e., deposited or attached matter that is a precursor of the film is removed. A chlorine-containing gas, e.g., Cl₂ or the like is used as an etching gas. The core as the precursor of the film or the state before the formation of the core is less stable than the silicon-containing film, and thus etching is performed at a lower temperature. Therefore, the dielectric surface such as the silicon oxide film surface or silicon nitride film surface can be cleaned by hardly etching the film epitaxially grown on the single crystal surface.

Note that the effect of the present invention can also be achieved by performing the etching in the state where the film is formed on the dielectric surface. However, when the etching is performed before the film is formed on the dielectric surface, the selective growth of the single crystal film (epitaxial film) on the single crystal surface is efficiently performed and surface roughness can be suppressed because of the following reasons. Thus, it is preferable that the etching is performed before the film is formed on the dielectric surface.

This is because the pre-core formation state before the film is formed is less stable than the state after the film is formed, and thus the etching is more easily performed. For example, the state before the film is formed has an advantage that the etching can be performed at a lower temperature than that after the film is formed. During the etching, the material in the state before the film is formed on the dielectric surface (material formed to be the core and/or pre-core formation material) can be selectively removed without etching much of the film formed on the single crystal surface. To be more specific, since the film formed on the dielectric surface and the epitaxial film formed on the single crystal surface are both the Si-containing film having a similar composition, a difference in stability for etching therebetween is assumed to be relatively small (compared with whether the film is formed or not) despite a slight difference in film quality attributable to crystallinity and the like. If the film is removed by etching after the film is formed on the dielectric surface, much of the epitaxial film deposited on the single crystal surface is also etched (resulting in inefficient selective growth and surface roughness on the epitaxial film). On the other hand, by performing the etching while stopping the deposition in the state before the film is formed on the dielectric surface (particularly, the state before the generation of the core), only the core generated on the dielectric surface can be easily etched without etching much of the epitaxial film already formed on the single crystal surface. Thus, selective epitaxial growth with a desired film thickness can be implemented by repeating the above operations.

As a result of manufacturing using the method shown in FIG. 4, a silicon-containing film can be epitaxially grown on the single crystal surface such as silicon, and an epitaxial film formed of the silicon-containing film can be selectively grown in a state where no film is formed on the dielectric surface such as the silicon oxide film surface or silicon nitride film surface or in a state where deposition on the dielectric surface is reduced.

Moreover, when only an epitaxially-grown film having a film thickness smaller than the desired film thickness can be obtained in one cycle of S1 to S4 shown in FIG. 4 described above, the process of S2 to S4 is further repeated until the desired film thickness is obtained. In other words, an In-Situ doped epitaxial film having a desired film thickness can be selectively grown by repeating the first deposition step, the second deposition step and the etching step.

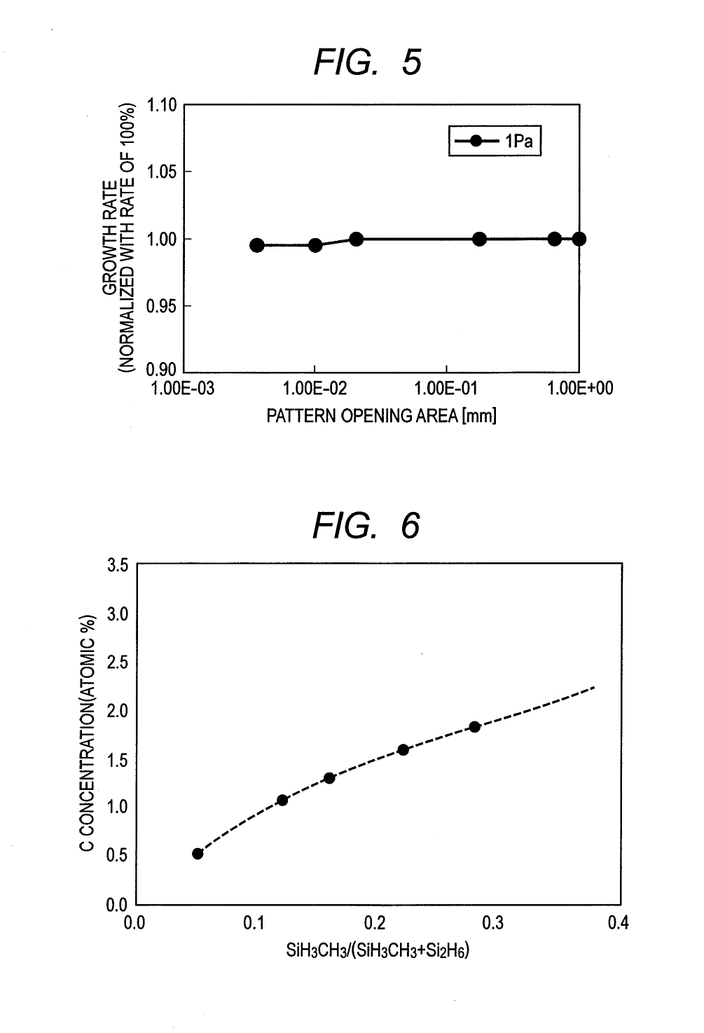

The pressure (process pressure) in the chamber during the introduction of the silicon-containing gas as the source gas and the doping gas is appropriately selected in each of the deposition steps. However, in order to implement the growth in which the growth rate is less dependent on a pattern opening area on the single crystal surface as the region where the doped epitaxial film is grown, it is preferable that the process pressure is as low as less than 10 Pa. FIG. 5 shows the dependency of the growth rate on the pattern opening area when the pressure is 1 Pa. FIG. 5 shows the dependency of the growth rate of the doped epitaxial film on the pattern opening area when the pattern opening area on the single crystal surface is normalized to 1 mm square (1 mm²). When In-Situ doping epitaxial growth is performed at a low pressure of 1 Pa, in the case of normalization assuming that the growth rate in 1 mm square (1 mm²) is 1, an amount of growth rate change is 0.5% or less even when the pattern opening area is changed to 0.8 mm², 0.4 mm², 0.14 mm², 0.1 mm² or 0.06 mm². While the lower limit of the process pressure is not particularly set, it is preferable that the lower limit, if there is any to be set, is 0.01 Pa or more from the viewpoint of the practical deposition rate. That is, it is preferable that the process pressure is 0.01 Pa or more and less than 10 Pa. Note that the gas supply unit 30 can control the carbon concentration and doping concentration by flow rate control.

As described above, the process pressure is set to less than 10 Pa, preferably, 0.01 Pa or more and less than Pa. Thus, a variation in the growth rate can be reduced even when the size of the region (the pattern opening area on the single crystal surface) is changed where the single crystal surface formed on the surface of the substrate 41 is exposed, the single crystal surface being the surface where the film is to be formed by selective growth.

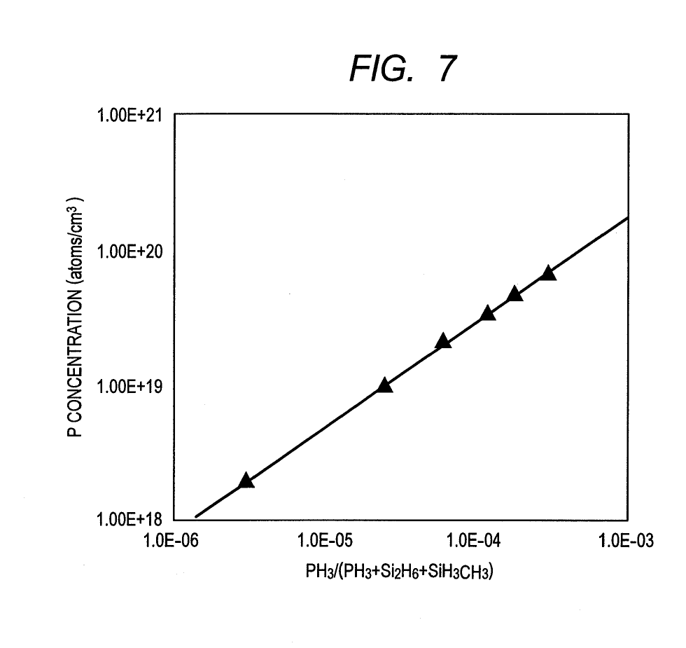

With reference to FIGS. 6 and 7, description is given of relationships between a gas flow ratio and a carbon concentration as well as between a gas flow ratio and a P doping concentration when each In-Situ doped epitaxial film is selectively grown using the method for selective growth according to the embodiment of the present invention. FIG. 6 is an explanatory graph showing a relationship between the carbon concentration and a ratio of a SiH₃CH₃ gas flow volume to the total supply gas flow volume (sum of flow volumes of supplied Si₂H₆ and SiH₃CH₃) for each epitaxial film when a mixed gas of Si₂H₆ and SiH₃CH₃ is used as the source gas in the case of the use of the selective growth method according to the embodiment of the present invention. FIG. 7 is an explanatory graph showing a relationship between the P concentration and a ratio of a PH₃ gas flow volume to the total supply gas flow volume (sum of flow volumes of supplied Si₂H₆, SiH₃CH₃ and PH₃) for each epitaxial film when a mixed gas of Si₂H₆ and SiH₃CH₃ is used as the source gas and PH₃ is used as the doping gas in the case of the use of the selective growth method according to the embodiment of the present invention.

FIGS. 6 and 7 show that the carbon concentration and the P doping concentration can be controlled by supplying various gases and controlling only the gas flow ratio using the thermal CVD apparatus according to the embodiment of the present invention. Moreover, the result of doping concentration measurement using a specific resistance and a secondary ion-microprobe mass spectrometer (SIMS) shows that an activation rate is 100%. This is considered to be because a pyrolysis reaction of the introduced gases is dominant when the deposition is performed using the thermal CVD apparatus according to the embodiment of the present invention. Therefore, according to the embodiment of the present invention, an epitaxial film having a desired doping concentration can be formed at a lower temperature than an activation anneal temperature without performing activation annealing after ion implantation unlike the conventional technology.

Table 1 shows a relationship between surface roughness and P doping concentration when each In-Situ doped epitaxial film is selectively grown using the method according to the embodiment of the present invention. As shown in Table 1, the surface flatness is significantly improved when the P doping concentration is 1×10¹⁹ atoms/cm³ or less. More specifically, according to Table 1, the surface roughness is found on the SEM surface when the P doping concentration is 5×10¹⁹ atoms/cm³ or more, while no surface roughness is found when the P doping concentration is 1×10¹⁹ atoms/cm³. In other words, the effect of reducing the surface roughness is significantly improved when the P doping concentration is 1×10¹⁹ atoms/cm³ or less. Therefore, in order to improve the surface flatness, it is preferable that the doping concentration of the second thin film is 1×10¹⁹ atoms/cm³ or less.

TABLE 1

P Doping Concentration

| | 1.0E+18 | 1.0E+19 | 5.0E+19 | 1.0E+20 |
|---|---|---|---|---|
| Surface | Not | Not | Present | Present |
| Roughness | Present | Present | | |

Moreover, an examination is made on a relationship between the surface roughness and the thickness of the second thin film in the selective growth method according to the embodiment of the present invention when the second thin film has less surface roughness and has the doping concentration of 1×10¹⁹ atoms/cm³ or less. The result shows that the surface roughness is found when the second thin film is 0 nm, that is, no second thin film is provided, while no surface roughness is found when the thickness of the second thin film is 0.5 nm. Since one atomic layer of the second thin film is assumed to be about 0.5 nm in thickness, the improvement in surface roughness indicates that the surface roughness can be improved by covering the first thin film with the second thin film.

More specifically, it is indicated that the surface roughness is improved when at least the second thin film having one atomic layer or more is substantially attached to the first thin film. Thus, the second thin film formed in the second deposition step need only have a thickness of one atomic layer or more.

Note that, for the purpose of maintaining good flatness of the film, there is no particular upper limit on the thickness of the film to be grown in the second deposition step. Moreover, in view of throughput and the like, it is preferable that the second thin film is formed to have a thickness as small as possible. On the other hand, if the thickness is too large, the doping concentration is no longer uniform in the film thickness direction. However, such a discussion about the acceptable value is not very practical, and the thickness should be determined based on whether or not the thickness affects electrical characteristic of the source/drain portion. As an example, after a MOSFET is formed using the deposition described above for selective growth of a source/drain portion, a contact hole is formed in the source/drain portion. Thereafter, an electrode is formed and then electrical characteristics thereof are checked. As a result, it is confirmed that, when the first thin film is 1 nm thick and has a doping concentration of 1×10²⁰ atoms/cm³ and the second thin film has a doping concentration of 1×10¹⁸ atoms/cm³, there is no problem with the electrical characteristics as long as the thickness of the second thin film is 2 nm or less.

As described above, according to the method and apparatus for selective growth of this embodiment, after the formation of the first thin film doped with high concentration of P or the like, the second thin film is grown and formed by low concentration doping of P or the like, and then etching is performed by applying Cl₂. Thus, surface roughness can be improved compared with the conventional selective growth of In-Situ doped epitaxial film. This is considered to be because although the epitaxial film doped with high concentration of P or the like is etched by Cl₂, etching with Cl₂ is suppressed by forming the epitaxial film doped with low concentration of P or the like as the surface.

More specifically, when a layer In-Situ doped with high concentration of P or the like is exposed to Cl₂, etching occurs and deteriorates surface flatness.

Accordingly, an alternate application method is used, in which a cap layer In-Situ doped with low concentration of P or the like is formed before exposure to Cl₂, and then Cl₂ is applied thereto. Moreover, more efficient selective growth can be performed compared with the conventional selective growth of In-Situ doped epitaxial film. Thus, selective growth process time can be reduced, and thereby productivity can be improved.

Furthermore, since the In-Situ doped epitaxial film according to the embodiment of the present invention is grown by the pyrolysis reaction of the introduced gas, the dopant is activated during the growth of the epitaxial film, thus eliminating the need for activation annealing. As a result, the productivity can be significantly improved compared with the conventional method requiring ion implantation. Moreover, since there is no need for activation annealing, problems such as dopant diffusion are solved, thereby enabling formation of a very thin source/drain layer.

As described above, according to the embodiment of the present invention, etching using the etching gas is performed in the state where the second thin film doped with less P or the like than the first thin film is formed on the first thin film doped with high concentration of P or the like. The second thin film with less doping than the first thin film is less likely to be etched with the etching gas than the first thin film. Accordingly, the second thin film functions as a protective film for the first thin film against the etching with the etching gas. Thus, selective etching can be performed using the second thin film substantially as a mask for the first thin film. As a result, even if the film is doped with high concentration of P or the like using the In-Situ doping selective growth involving simultaneous supply of the source gas and the doping gas, deterioration in the surface flatness of the epitaxial film selectively grown on the single crystal surface can be reduced. Moreover, the epitaxial film doped with high concentration of P or the like and with less deterioration in surface flatness can be formed.

Here, the second thin film described above is formed of the same material and doped in the same manner as the first thin film, and there is no particular problem with the electrical characteristics as long as the film thickness or the like of the second thin film is appropriately set based on the user acceptable value as described above. Thus, there is also no need to remove the second thin film as the mask against the etching. This is because the second thin film can not only function as the mask against the etching but also function as a part of the epitaxial film to be formed. Thus, selective etching of the dielectric on the substrate 41 can be performed without additionally providing the mask for the epitaxial film for selective etching.

More specifically, in the present invention, the first thin film doped with high concentration of P or the like is formed, and then the second thin film doped with less P or the like than the first thin film is formed on the first thin film, and thereafter, etching is performed using the etching gas. As a result, the selective growth of the epitaxial film doped with P or the like and the selective etching to remove the deposit formed on the dielectric while maintaining the flatness of the epitaxial film can be simultaneously performed.

Note that, in the above description, it is illustrated that the doping concentration of P into the second thin film is 1×10¹⁹ atoms/cm³ or less as an example of the criteria for suppressing the deterioration in flatness in the case of P doping. However, it is not an essential point to set the low concentration of P doping for the second thin film to the above value or less. “Setting the doping concentration of P into the second thin film to 1×10¹⁹ atoms/cm³ or less” is just one of the criteria. In the present invention, focusing on the fact that the surface roughness due to etching using the etching gas is eliminated or reduced by reducing the doping concentration, as shown in Table 1, it is essential that the second thin film is formed with a doping concentration which at least reduces the etching using the etching gas compared with the high concentration doping. Therefore, the etching using the etching gas for the second thin film need only be reduced compared with the desired high concentration doping. Thus, the second thin film need only be formed with a predetermined doping concentration lower than the desired high doping concentration.

Therefore, the present invention is applicable if the etching using the etching gas is reduced by setting the doping concentration of the second thin film to be lower than the doping concentration of the first thin film even when the film is doped with As or the like other than P.

The present invention is described in more detail below by taking an example and a comparative example of the method for selectively growing an In-Situ doped epitaxial film according to the present invention.

### Example

In this example, description is given of the case where a highly P-doped SiC is formed using the method for selective growth according to the embodiment of the present invention.

The selective growth apparatus (thermal CVD apparatus) according to the embodiment of the present invention having the configuration shown in FIGS. 1 to 3 is used, and a substrate with an oxide film (dielectric) having a thickness of 100 nm patterned on a surface of an 8-inch Si (100) plate is used as the substrate 41.

In this example, description is first given up to the point when the substrate 41 is carried and set in the deposition chamber 15. Then, the method for selectively growing an epitaxial film is described.

First, description is given up to the point when the substrate is carried and set in the deposition chamber.

A natural oxide film formed by oxygen, moisture and the like in the atmosphere, or metal components and organic components adhere to the exposed Si uppermost surface of the substrate 41 with the oxide film pattern. Thus, the substrate is washed with a hydrochloric peroxide mixture or an ammonia hydrogen peroxide solution to remove such a film or components. Thus, a silicon oxide film (SiO₂ film) having a thickness of about 2 nm is generally formed on the surface of the Si layer. The silicon oxide film is removed beforehand by etching in a diluted hydrofluoric acid solution. The surface of the Si layer treated with the diluted hydrofluoric acid solution is terminated with hydrogen (H).

The substrate 41 with the oxide film pattern is mounted on the susceptor 22 in the deposition chamber 15 through the exchange chamber 11 and the carrier chamber 14 as described above. The inside of the deposition chamber 15 is evacuated to ultrahigh vacuum of, for example, 5×10⁻⁷ Pa. In the deposition chamber 15, the substrate 41 with the oxide film pattern mounted on the susceptor 22 is further heated to about 600° C., which is the pyrolysis temperature of the Si-containing gas or more, by the heater 23.

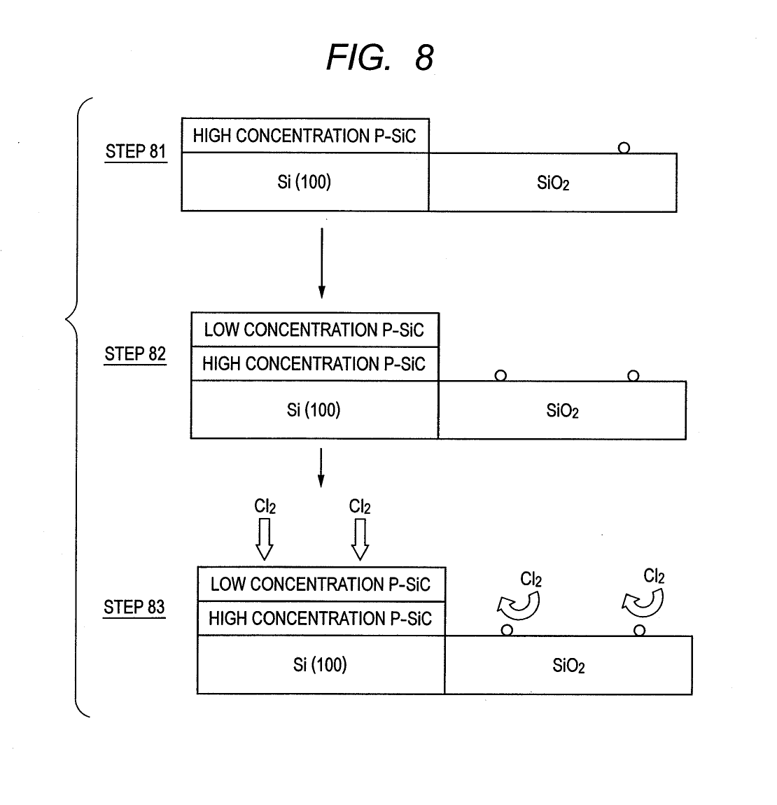

Next, description is given of the method for selectively growing a P-doped SiC epitaxial film on Si exposed on the substrate surface. FIG. 8 is an explanatory view showing the selective growth method according to the example.

In this example, first, as shown in Step 81 of FIG. 8, Si₂H₆ and SiH₃CH₃ as the source gas and PH₃ as the doping gas are simultaneously supplied onto the substrate 41 preheated to 600° C. described above in the deposition chamber 15, and the pressure in the deposition chamber is set to 0.1 Pa. Thus, a highly P-doped epitaxial SiC film (first thin film) is grown. Then, the PH₃ gas supply is stopped so as to set the P concentration to be as low as 1×10¹⁹ atoms/cm³ or less as shown in Step 82 of FIG. 8 well before the film is formed on SiO₂ as a dielectric formed on the substrate 41. Meanwhile, the supply of the Si₂H₆ gas and SiH₃CH₃ gas is continued, and the pressure in the deposition chamber is maintained at 0.1 Pa. Thus, an epitaxial SiC film (second thin film) doped with low concentration of P is grown. Subsequently, the supply of the Si₂H₆ gas and SiH₃CH₃ gas is stopped prior to core generation before the film is formed on SiO₂ as the dielectric formed on the substrate 41. Thus, the deposition is stopped. Thereafter, Cl₂ gas is supplied as an etching gas as shown in Step 83 of FIG. 8, thus removing the core formed on SiO₂.

Then, Steps 81 to 83 of FIG. 8 are further repeated for 49 times until the film thickness reaches about 100 nm.

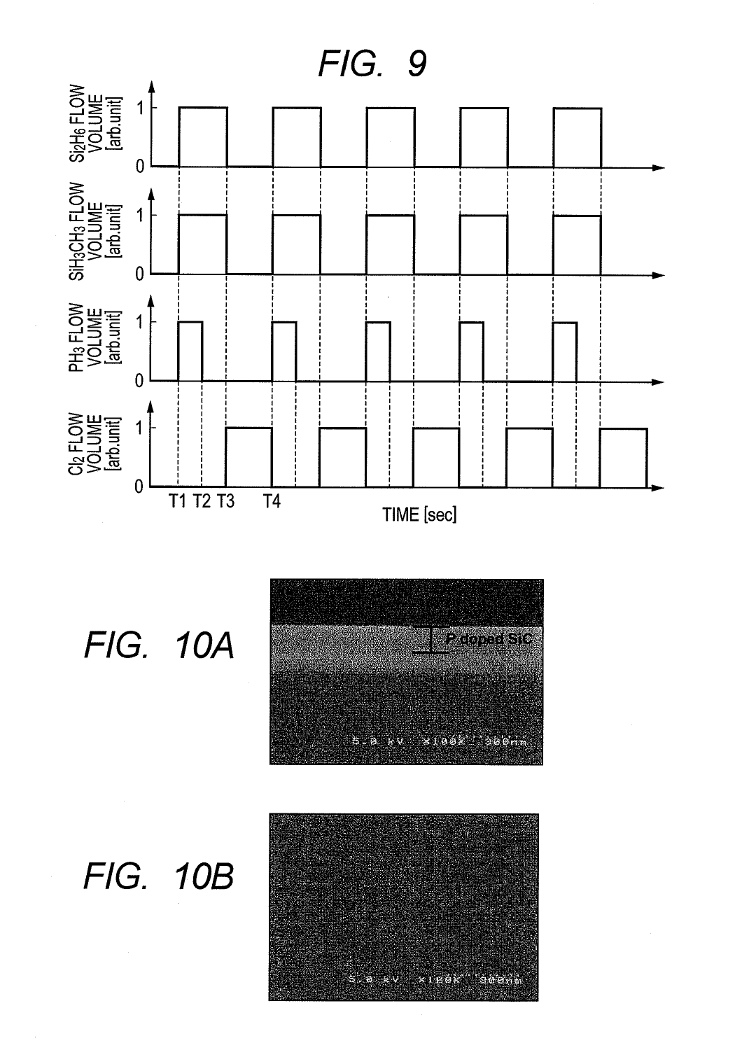

FIG. 9 is a view showing a part of a time chart for introduced gases (Si₂H₆, SiH₃CH₃, PH₃ and Cl₂) in the example. The horizontal axis represents time while the vertical axis represents an introduced flow volume (relative value) of each of the introduced gases.

As shown in FIG. 9, after the substrate temperature reaches 600° C., introduction of Si₂H₆ and SiH₃CH₃ as the source gas and PH₃ as the doping gas is started at time T1. Next, the PH₃ supply is stopped at time T2. Then, at time T3, the Si₂H₆ and SiH₃CH₃ supply is stopped and introduction of Cl₂ as the etching gas is started. Thereafter, the Cl₂ supply is stopped at time T4. Furthermore, at T4, introduction of Si₂H₆, SiH₃CH₃ and PH₃ is started to restart the deposition. Then, the above steps are repeated. To be more specific, the process between T1 and T2 corresponds to a first deposition step, the process between T2 and T3 corresponds to a second deposition step, and the process between T3 and T4 corresponds to an etching step.

Note that the time chart for the introduced gases is not limited to that described above. For example, the doping gas PH₃ supply does not have to be completely stopped at T2, but may be just reduced. In this case, the amount of PH₃ supply from T2 to T3 needs to be reduced so that the P doping amount of the film deposited during that time is 1×10¹⁹ atoms/cm³ or less. At T3, the supply of PH₃ as well as Si₂H₆ and SiH₃CH₃ needs to be stopped. Moreover, time without any gas supply may be provided between the first deposition step to form the first thin film layer and the second deposition step to form the second thin film layer. Furthermore, time without any gas supply may be provided between the second deposition step and the etching step to introduce the etching gas containing chlorine. Here, the time without any gas supply is called an evacuation time. In view of contamination, it is sometimes better to provide the evacuation time. On the other hand, provision of the evacuation time increases the process time for each cycle. Therefore, it should be determined, based on the design requirements of the film and apparatus, whether or not the evacuation time is provided and, if so, how long the evacuation time should be.

FIGS. 10A and 10B show photographs of the cross-section and surface of the P-doped SiC film epitaxially selectively grown as described above, the photographs being taken as a result of observation with a scanning electron microscope. FIG. 10A is a view showing an SEM photograph of the cross-section, while FIG. 10B is a view showing an SEM photograph of the surface. As shown in FIGS. 10A and 10B, no surface roughness is observed. This is considered to be because P atoms on the surface are reduced by inserting a low-concentration P-doped layer formation step (the second deposition step) before the chlorine gas application step (the etching step), and thus the selective P etching is suppressed and the surface roughness is eliminated.

Note that approximately the same effect is achieved using PH₃ diluted with a gas that does not affect the process, more specifically, an H₂-diluted PH₃ instead of the PH₃ gas as the doping gas.

### Comparative Example

In this comparative example, description is given of the case where a highly P-doped SiC is formed, using the conventional selective growth method, on a substrate prepared using the same method and the thermal CVD apparatus having the same configuration as that in the example described above. The processing in this comparative example is performed under the same conditions, unless otherwise described, as those in the example described above.

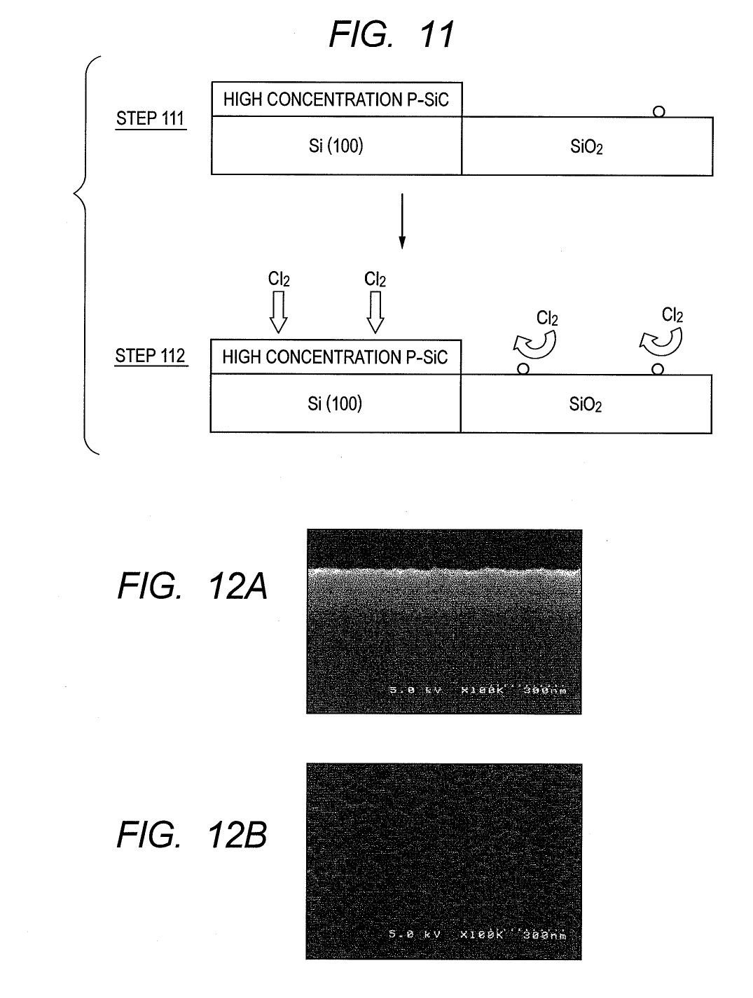

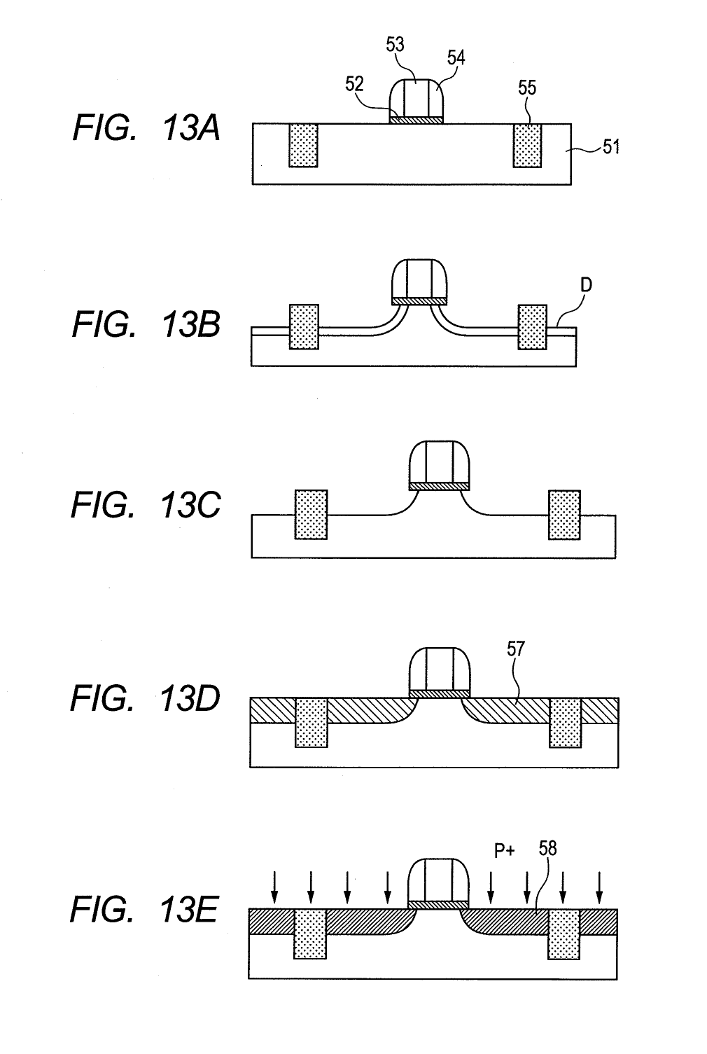

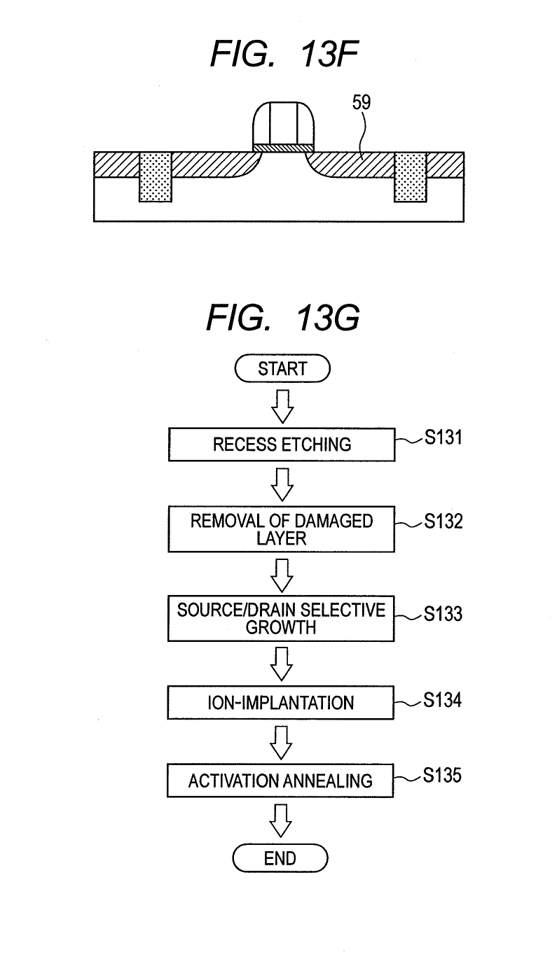

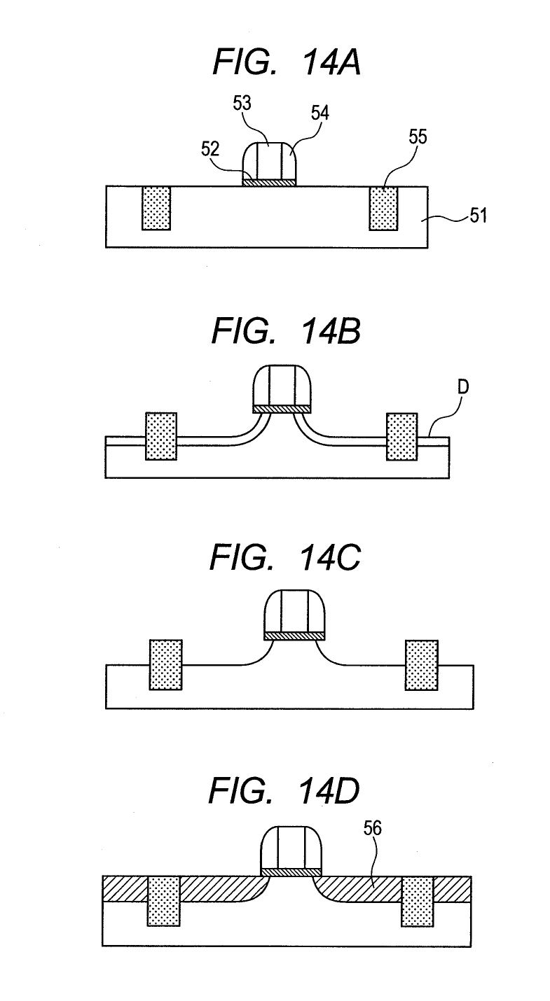

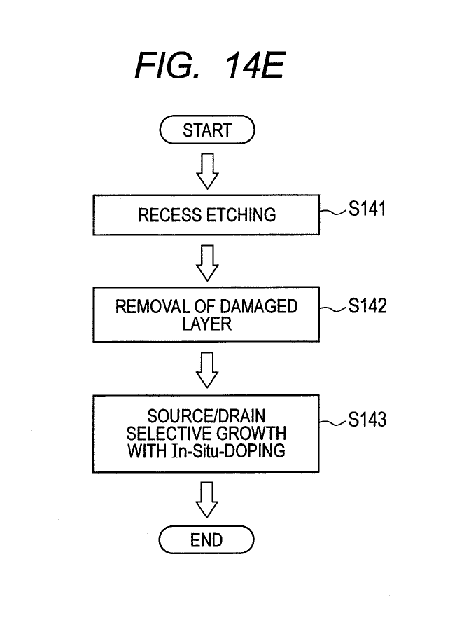

FIG. 11 is an explanatory view showing a selective growth method according to the comparative example. Si₂H₆ and SiH₃CH₃ as the source gas and PH₃ as the doping gas are simultaneously supplied onto the substrate prepared in the same manner as that in the example and preheated to 600° C. described above in the deposition chamber 15, and the pressure in the deposition chamber is set to 0.1 Pa. Thus, a highly P-doped epitaxial SiC film is grown by the pyrolysis reaction as shown in Step 111 of FIG. 11. Subsequently, the supply of Si₂H₆, SiH₃CH₃ and PH₃ is stopped prior to core generation before the film is formed on SiO₂. Thereafter, chlorine gas is supplied as shown in Step 112 of FIG. 11, thus removing the core formed on SiO₂. Then, the above Step 111 and Step 112 is repeated for 99 times until the film thickness reaches about 100 nm, which is the same as the example. The reason why the steps are repeated for 100 times in this comparative example, while the total number of repeating the steps is 50 in the example, is because the selective growth rate is slow.

The reason why the selective growth rate is slow in this comparative example is considered to be because not only the core generated on the SiO₂ surface is removed in the step (etching step) of exposing chlorine to the substrate but also the P-doped SiC film deposited on the Si exposed surface is also considerably etched. Thus, the film thickness of the P-doped SiC film that can be deposited in one cycle of the deposition and chlorine exposure steps in this comparative example is only about half of that in the case of the example described above. About twice as many cycle repetitions is required to obtain the same film thickness as that in the example. Therefore, in this comparative example, it takes twice as long as the example to selectively grow the P-doped SiC having the same film thickness as the example.

FIGS. 12A and 12B show photographs of the cross-section and surface of the P-doped SiC film selectively grown in this comparative example as described above, the photographs being taken as a result of observation with a scanning electron microscope. The photographs of the cross-section (FIG. 12A) and surface (FIG. 12B) show surface roughness. The P doping concentration in this process is 1×10²° atoms/cm³. This surface roughness is considered to be because many P atoms are on the surface in the case of high concentration P doping, and since the bond energy of P and Si is smaller than Si—Si bond, P is selectively etched by Cl₂.

1. A method for selectively growing a doped epitaxial film, comprising:
a first step of forming a first thin film by epitaxial growth, while a source gas and a doping gas are supplied so that a dopant having a concentration exceeding 5×10¹⁹ atoms/cm³ is doped on a single crystal surface of a preheated substrate having the single crystal surface and a dielectric surface as a processing surface;
a second step of supplying the source gas and the doping gas before a film is formed on the dielectric surface, the doping gas supplied so that the dopant concentration is not more than 1×10¹⁹ atoms/cm³, to form, by epitaxial growth, a second thin film doped with the dopant at lower concentration than the first thin film, on a surface of the first thin film; and
an etching step of stopping supply of the source gas before a film is formed on the dielectric surface, and exposing the processing surface of the substrate to an etching gas with the second thin film as a mask, thereby removing a material adhering to the dielectric surface.

2. The method for selectively growing a doped epitaxial film, according to claim 1, wherein
in the first step, the first thin film is formed on the single crystal surface by exposing the processing surface of the substrate to a doping gas at a first flow ratio of the doping gas to a source gas, and
in the second step, the second thin film is formed on the surface of the first thin film by exposing the processing surface of the substrate to the doping gas at second flow ratio of the doping gas to the source gas.

3. The method for selectively growing a doped epitaxial film, according to claim 1, wherein
in the first step, formation of the first thin film is stopped before a film is formed on the dielectric surface.

4. The method for selectively growing a doped epitaxial film, according to claim 1, wherein
the second flow ratio is smaller than the first flow ratio or zero.

5. The method for selectively growing a doped epitaxial film, according to claim 2, wherein
in the second step, supply of the doping gas is not performed.

6. The method for selectively growing a doped epitaxial film, according to claim 1, wherein
the single crystal is silicon (Si (100)), and
the dielectric is a silicon oxide film or a silicon nitride film.

7. The method for selectively growing a doped epitaxial film, according to claim 2, wherein
the source gas, the dopant, and the doping gas to form the first and second thin films are a Si-containing gas, phosphorus (P), and a phosphorus (P)-containing gas, respectively.

8. (canceled)

9. The method for selectively growing a doped epitaxial film, according to claim 2, wherein
the pressure in the chamber where the substrate is disposed during introduction of the source gas and the doping gas in the first and second steps is not less than 0.01 Pa and less than 10 Pa.

10. The method for selectively growing a doped epitaxial film, according to claim 1, wherein
the first step, the second step and the etching step are performed, as a series of steps, more than once sequentially.

11-12. (canceled)
